(19) United States
(12) Patent Application Publication
(10) Pub. No.: US 2025/0327909 A1
(43) Pub. Date: Oct. 23, 2025

(54) DISTANCE MEASURING DEVICE AND DISTANCE MEASURING SYSTEM

(71) Applicant: SONY SEMICONDUCTOR SOLUTIONS CORPORATION, KANAGAWA (JP)

(72) Inventors: KAZUTOSHI TOMITA, KANAGAWA (JP); YASUNORI TSUKUDA, KANAGAWA (JP)

(21) Appl. No.: 18/864,565

(22) PCT Filed: May 11, 2023
(86) PCT No.: PCT/JP2023/017684

§ 371 Date: Nov. 11, 2024

(30) Foreign Application Priority Data
May 18, 2022 (JP) 2022-081902

(51) Int. Cl. G01S 7/487; G01S 7/4863

(52) U.S. Cl. CPC G01S 7/4873; G01S 7/4863

(57) ABSTRACT

To perform accurate distance measurement from the distance measuring start point even when the surrounding brightness changes suddenly. A distance measuring device includes: a light receiving unit that receives a reflected light pulse signal reflected by an object; a distance measuring unit that performs distance measuring processing on the basis of an output signal of the light receiving unit; and a bias control unit that controls a bias voltage of the light receiving unit before the distance measuring unit starts the distance measuring processing.

### TECHNICAL FIELD

The present technology relates to a distance measuring device and a distance measuring system.

### BACKGROUND ART

In a distance measuring device of a time of flight (ToF) method, a single-photon avalanche diode (SPAD) is often used to receive a reflected light pulse signal from an object. The SPAD has a detection capability of being able to detect one photon. Usually, a light receiving chip in which a plurality of SPADs is aligned in a two-dimensional direction is used.

However, there is a problem that a breakdown voltage between the anode and the cathode of the SPAD changes according to the temperature, and detection sensitivity of the SPAD varies depending on the temperature. Therefore, a technique has been proposed in which an anode voltage of the SPAD is controlled according to the temperature so that a cathode voltage of the SPAD in response to light does not fluctuate depending on the temperature (see, for example, Patent Document 1).

### CITATION LIST

### Patent Document

Patent Document 1: Japanese Patent Application Laid-Open No. 2021-56016

### SUMMARY OF THE INVENTION

### Problems to be Solved by the Invention

For example, in a case where the distance measuring device is applied to automated driving or the like, there is a case where the brightness in the vicinity of where a distance measurement target object is located changes suddenly. For example, as soon as a vehicle traveling inside a tunnel leaves the tunnel, the surroundings of the vehicle suddenly become bright. Furthermore, some systems including the distance measuring device have a function of switching between a long-distance distance measuring mode and a middle/short-distance distance measuring mode. A light emitting unit for distance measurement causes only a part of light emitting elements to emit light in the long-distance distance measuring mode, but there are cases where more light emitting elements are made to emit light in the middle/short-distance distance measuring mode. In this case, more SPADs react in the middle/short-distance distance measuring mode than in the long-distance distance measuring mode.

As described above, when the surrounding brightness changes suddenly, the number of SPADs reactive to light greatly changes, and the temperature of a chip of the SPAD changes accordingly.

In Patent Document 1, because the sudden change in the surrounding brightness is not taken into consideration, there is a possibility that the distance measuring accuracy decreases for a while after the surrounding brightness changes suddenly.

The present technology has been made in view of such a situation, and provides a distance measuring device and a distance measuring system that enable accurate distance measurement to be performed from a distance measuring start time point even when the surrounding brightness changes suddenly.

### Solutions to Problems

In order to solve the problem described above, according to the present disclosure, there is provided a distance measuring device including: a light receiving unit that receives a reflected light pulse signal reflected by an object; a distance measuring unit that performs distance measuring processing on the basis of an output signal of the light receiving unit; and a bias control unit that controls a bias voltage of the light receiving unit before the distance measuring unit starts the distance measuring processing.

The bias control unit may control a bias voltage of the light receiving unit in a first period before the distance measuring unit starts the distance measuring processing and a second period during which the distance measuring processing is performed.

The first period may include a partial period immediately before the distance measuring processing is started among a period in which the distance measuring processing is not performed.

The light receiving unit may include: a first light receiving element used for the distance measuring processing; and
a second light receiving element used to control the bias voltage.

The light receiving unit may include: a first light receiving element used for the distance measuring processing; and
a second light receiving element used to control the bias voltage, and the first light receiving element may perform a light receiving operation within a period in which the second light receiving element controls the bias voltage.

The light receiving unit may include: a plurality of first light receiving elements used in the distance measuring processing; and a second light receiving element used to control the bias voltage, and a part of the first light receiving elements among the plurality of first light receiving elements may perform a light receiving operation within a period in which the second light receiving element controls the bias voltage.

There may be provided a pixel array unit including the plurality of first light receiving elements, in which the part of the first light receiving elements may be two or more first light receiving elements obtained by thinning out the plurality of first light receiving elements in the pixel array unit.

The bias control unit may control the bias voltage on the basis of a voltage level of an output signal of the light receiving unit before the distance measuring unit starts the distance measuring processing.

The bias control unit may control the bias voltage on the basis of a voltage level of an output signal of the light receiving unit that has received the reflected light pulse signal before the distance measuring unit starts the distance measuring processing.

The bias voltage may be controlled to cause a cathode voltage or an anode voltage of the first light receiving element to become a predetermined voltage level when the first light receiving element receives the reflected light pulse signal.

The bias control unit may control the bias voltage on the basis of the number of crossing times between an output signal of the light receiving unit and a predetermined threshold.

The light receiving unit may include a plurality of light receiving elements, and the bias control unit may control the bias voltage on the basis of the number of crossing times between output signals of at least a part of light receiving elements among the plurality of light receiving elements and a predetermined threshold.

There may be provided: a number-of-times counting unit that counts the number of crossing times; a storage unit that stores a correspondence relationship between the number of times that an output signal of the light receiving unit crosses a predetermined threshold and an output signal level of the light receiving unit; and a storage control unit that reads, from the storage unit, the output signal level corresponding to the number of times counted by the number-of-times counting unit, in which the bias control unit may control the bias voltage on the basis of the output signal level read by the storage control unit.

The storage unit may store a correspondence relationship between the number of times that an output signal of the light receiving unit crosses a predetermined threshold, the output signal level of the light receiving unit, and the temperature.

The number-of-times counting unit may count the number of times that an output signal of the light receiving unit crosses the predetermined threshold, the light receiving unit having received the reflected light pulse signal before the distance measuring unit starts the distance measuring processing.

According to another aspect of the present disclosure, there is provided a distance measuring system that further includes: the distance measuring device described above; and a light emitting unit that emits a light pulse signal, in which the light receiving unit receives the reflected light pulse signal obtained by reflecting the light pulse signal by the object.

The light emitting unit may emit the light pulse signal during a period in which the distance measuring processing is performed and a period in which the bias control unit controls a bias voltage of the light receiving unit before starting the distance measuring processing.

The distance measuring unit may measure a distance to the object on the basis of a time difference between a light emission timing of the light pulse signal by the light emitting unit and a light reception timing of the reflected light pulse signal by the light receiving unit.

The light emitting unit may include a plurality of light emitting elements each of which emits the light pulse signal,
the light emitting unit may have a first mode of causing one or more first number of pieces of the light emitting elements to simultaneously emit light at a time when the distance measuring unit measures a distance to the object within a first distance range, and a second mode of causing a second number of pieces of the light emitting elements less than the first number of pieces to simultaneously emit light at a time when the distance measuring unit measures a distance to the object within a second distance range wider than the first distance range, and,
in the first mode, the light emitting unit may cause the first number of pieces of light emitting elements to simultaneously emit light in a period in which the distance measuring unit performs the distance measuring processing and before the distance measuring unit starts the distance measuring processing, and in the second mode, the light emitting unit may not cause the second number of pieces of light emitting elements to simultaneously emit light before the distance measuring unit starts the distance measuring processing and causes the second number of pieces of light emitting elements to simultaneously emit light within a period in which the distance measuring unit performs the distance measuring processing.

### BRIEF DESCRIPTION OF DRAWINGS

FIG. 1 is a block diagram illustrating a configuration example of a distance measuring system according to a first embodiment of the present technology.

FIG. 2 is a diagram illustrating an example of a distance measuring device according to the first embodiment of the present technology.

FIG. 3 is a plan view illustrating a configuration example of a pixel chip according to the first embodiment of the present technology.

FIG. 4 is a block diagram illustrating a configuration example of a circuit chip according to the first embodiment of the present technology.

FIG. 5 is a block diagram illustrating a configuration example of a circuit block according to the first embodiment of the present technology.

FIG. 6 is a block diagram illustrating an example of a monitor pixel according to the first embodiment of the present technology.

FIG. 7 is a block diagram illustrating an example of a distance measuring pixel according to the first embodiment of the present technology.

FIG. 8 is a diagram illustrating an example of fluctuation of a cathode voltage in a SPAD.

FIG. 9 is a diagram illustrating an example in which excess bias in the SPAD is small.

FIG. 10 is an explanatory diagram of spotlight and floodlight.

FIG. 11 is an operation timing diagram related to distance measuring processing and bias control.

FIG. 12 is an operation timing diagram of a distance measuring device and a light emitting unit according to the first embodiment of the present technology.

FIG. 13A is an explanatory diagram of a capture period in a case where calculation processing for distance measurement is performed inside the distance measuring device.

FIG. 13B is an explanatory diagram of the capture period in a case where calculation processing for distance measurement is performed outside the distance measuring device.

FIG. 14 illustrates a circuit operation of the distance measuring device during a distance measuring stop period according to the first embodiment of the present technology.

FIG. 15 is a diagram illustrating a circuit operation of the distance measuring device during the distance measuring stop period according to a second embodiment of the present technology.

FIG. 16 is a diagram illustrating a circuit operation of the distance measuring device during the distance measuring stop period according to a third embodiment of the present technology.

FIG. 17 is an operation timing diagram of the distance measuring device and the light emitting unit according to a fourth embodiment of the present technology.

FIG. 18A is a diagram illustrating a circuit operation of the distance measuring device in a period from a start point of the distance measuring stop period to several frames before the start of a distance measuring period according to the fourth embodiment of the present technology.

FIG. 18B is a diagram illustrating a circuit operation of the distance measuring device immediately before the distance measuring period according to the fourth embodiment of the present technology.

FIG. 19 is an operation timing diagram of the distance measuring device and the light emitting unit according to a fifth embodiment of the present technology.

FIG. 20 is an operation timing diagram of the distance measuring device and the light emitting unit according to a sixth embodiment of the present technology.

FIG. 21 is a diagram illustrating a circuit operation of the distance measuring device in a case where a count value is monitored only by a monitor pixel among the monitor pixel and a distance measuring pixel during the distance measuring stop period according to the sixth embodiment of the present technology.

FIG. 22 is a diagram illustrating a data configuration of a storage unit according to the sixth embodiment of the present technology.

FIG. 23 is a flowchart illustrating a processing operation of the distance measuring device according to the sixth embodiment of the present technology.

FIG. 24 is a diagram illustrating a circuit operation of the distance measuring device in a case where the count value is monitored only by a part of the distance measuring pixel among the monitor pixel and the distance measuring pixel during the distance measuring stop period according to the sixth embodiment of the present technology.

FIG. 25 is an operation timing diagram of the distance measuring device and the light emitting unit according to a seventh embodiment of the present technology.

FIG. 26 is an operation timing diagram of the distance measuring device and the light emitting unit according to an eighth embodiment of the present technology.

FIG. 27 is a block diagram illustrating an example of a schematic configuration of a vehicle control system.

FIG. 28 is an explanatory diagram illustrating an example of installation positions of an outside-vehicle information detecting section and an imaging section.

### MODE FOR CARRYING OUT THE INVENTION

Hereinafter, embodiments of a distance measuring device will be described with reference to the drawings. Hereinafter, a main configuration, a circuit, a table model, and the like of the distance measuring device will be described, but the distance measuring device may have components and functions that are not illustrated or described. The following description does not exclude components and functions that are not illustrated or described.

### First Embodiment

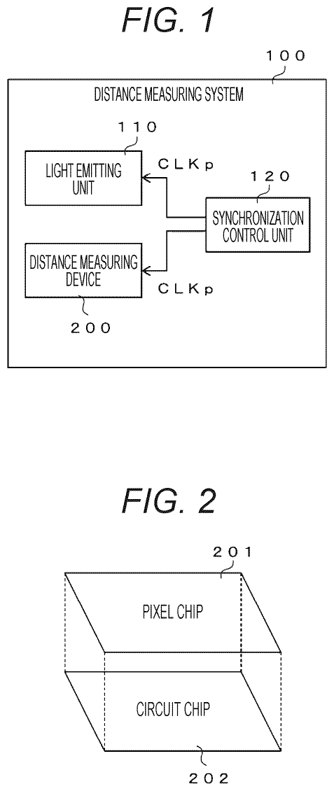

FIG. 1 is a block diagram illustrating a configuration example of a distance measuring system 100 according to a first embodiment of the present technology. The distance measuring system 100 measures a distance to an object by light irradiation, and is assumed to be mounted on a vehicle-mounted light detection and ranging (LiDAR) or the like. The distance measuring system 100 includes a light emitting unit 110, a synchronization control unit 120, and a distance measuring device 200. At least one of the light emitting unit 110 and the synchronization control unit 120 can have a configuration of being integrated with the distance measuring device 200.

The synchronization control unit 120 performs control to operate the light emitting unit 110 and the distance measuring device 200 in synchronization. The synchronization control unit 120 operates the light emitting unit 110 and the distance measuring device 200 in synchronization with a synchronization signal CLKp of a predetermined frequency.

The light emitting unit 110 intermittently emits, for example, a light pulse signal in a frequency band of near-infrared light in synchronization with the synchronization signal CLKp.

The distance measuring device 200 receives a reflected light pulse signal obtained by the light pulse signal from the light emitting unit 110 irradiating the object and being reflected therefrom, and calculates a distance to the object. In the case of the direct time of flight (dToF) method, the distance measuring device 200 measures a round-trip time from light emission timing of the light emitting unit until timing at which the reflected light pulse signal is received. The distance measuring device 200 calculates the distance to the object from the measured round-trip time, and generates and outputs distance data indicating the distance. Alternatively, the distance measuring device 200 may perform a part of the distance measuring processing until light reception timing of the reflected light pulse signal from the object is estimated, and the remaining processing of the distance measuring processing may be performed outside the distance measuring device 200.

### [Configuration Example of Distance Measuring Device]

The distance measuring device according to the present embodiment can be constituted of a semiconductor chip. FIG. 2 is a diagram illustrating an example of a chip configuration of the distance measuring device 200. The distance measuring device 200 in FIG. 2 is constituted of a stacked structure in which a pixel chip 201 and a circuit chip 202 are stacked. These chips are connected by Cu—Cu bonding or the like to transmit various signals. Note that the pixel chip 201 and the circuit chip 202 may be connected by a via, a bump, or the like other than Cu—Cu bonding.

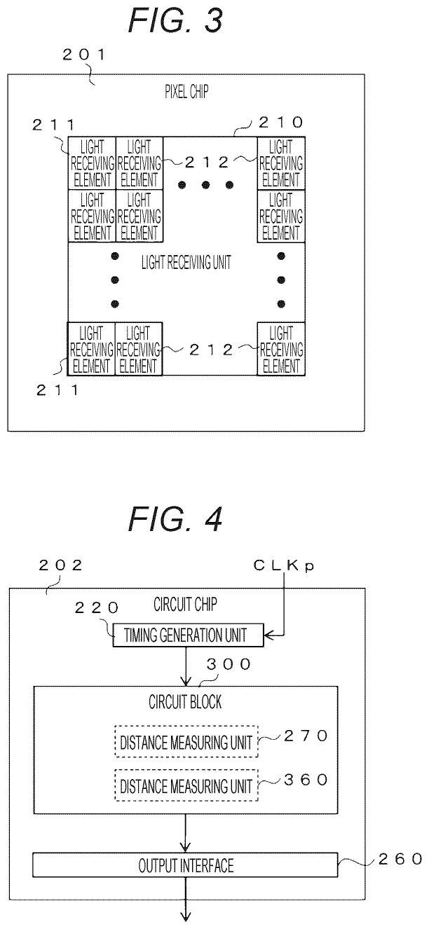

FIG. 3 is a plan view illustrating a configuration example of the pixel chip 201. This pixel chip 201 is provided with a light receiving unit 210. In the light receiving unit 210, a plurality of light receiving elements 211 and a plurality of light receiving elements 212 are aligned. As will be described later, the light receiving element 211 is provided to monitor a change in the output voltage of the light receiving unit 210 due to a temperature change. The light receiving element 212 is provided to perform the distance measuring processing. The light receiving elements 211 are linearly aligned, for example, along one end part of the light receiving unit 210. Note that an arrangement place and the number of light receiving elements 211 are optional. On the other hand, the light receiving elements 212 are aligned in, for example, a two-dimensional lattice pattern.

FIG. 4 is a block diagram illustrating a configuration example of the circuit chip 202. This circuit chip 202 includes a timing generation unit 220, a circuit block 300, and an output interface 260. Distance measuring units 270 and 360 are provided inside the circuit block 300. The distance measuring unit 270 performs the distance measuring processing by using a distance measuring pixel 402. The distance measuring unit 360 performs the distance measuring processing by using a monitor pixel 401. The distance measuring unit 270 is essential, but the distance measuring unit 360 is not essential and may be omitted. Note that the distance measuring units 270 and 360 may be provided separately from the circuit block 300.

As will be described later, a time-to-digital conversion unit, a histogram generation unit, a distance calculation unit, and the like are provided inside the distance measuring units 270 and 360.

As described above, the timing generation unit 220 performs control to operate the light receiving unit 210 in synchronization with the light emission timing of the light emitting unit 110.

In the circuit block 300, a plurality of pixel circuits is aligned. A part of the pixel circuits are connected to the above-described light receiving element 212 to constitute the distance measuring pixel 402. Details of the circuit block 300 will be described later. In the present description, the left-right direction of the circuit block in FIG. 4 is referred to as a column direction, and the up-down direction is referred to as a row direction.

Time-to-digital converters in the distance measuring units 270 and 360 generate digital signals corresponding to the time at which a signal level of a photoelectric conversion signal according to the reflected light pulse signal output from the pixel circuit in the circuit block 300 falls below a threshold. This digital signal indicates detection timing of photons. The time-to-digital converter supplies the digital signal to the histogram generation unit.

In FIG. 4, because the digital signals are generated without dividing the circuit blocks into even rows and odd rows, the configuration of the circuit chip 202 can be reduced in area, but because the digital signals are generated in all the pixel circuits in the circuit chip 202, power consumption increases.

The histogram generation units in the distance measuring units 270 and 360 generate histograms on the basis of the digital signal generated by the time-to-digital converter. Here, the histogram is a graph indicating the frequency of the light reception timings of the plurality of reflected light pulse signals. The histogram generation unit in the distance measuring unit 270 generates a histogram for one or more distance measuring pixels 402, and obtains the timing of each peak value as the light reception timing of the reflected light. The histogram generated by the histogram generation unit is used to measure the distance to the object. For example, in the case of the dToF method, the time corresponding to a peak position where the frequency of the histogram is the maximum is set as the light reception timing, and the distance to the object is calculated from a time difference from the light emission timing of the light emitting unit 110 to the light reception timing of the light receiving unit 210. The distance to the object is calculated for every distance measuring pixel 402 and is output to the outside via the output interface 260.

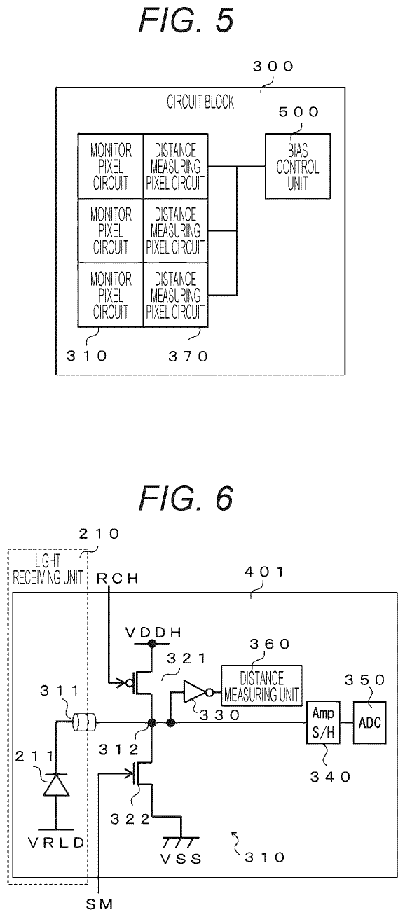

FIG. 5 is a detailed block diagram of the circuit block 300 in FIG. 4. In the circuit block 300 in FIG. 5, a plurality of monitor pixel circuits 310, a plurality of distance measuring pixel circuits 370, and a bias control unit 500 are disposed.

The monitor pixel circuit 310 is disposed for every light receiving element 211 and is connected to the corresponding light receiving element 211. The light receiving element 211 and the monitor pixel circuit 310 connected to this light receiving element 211 constitute one monitor pixel 401.

The distance measuring pixel circuit 370 is disposed for every light receiving element 212 and is connected to the corresponding light receiving element 212. The light receiving element 212 and the distance measuring pixel circuit 370 corresponding to this light receiving element 212 constitute one distance measuring pixel 402. This distance measuring pixel 402 detects photons and generates a pulsed photoelectric conversion signal.

The bias control unit 500 controls the voltage of either the cathode or the anode of the light receiving elements 211 and 212 on the basis of the detection result of photons by the monitor pixel 401.

Hereinafter, in the present description, the anode voltage of the light receiving elements 211 and 212 will be described as a control target by the bias control unit 500, and the cathode voltage will be described as a monitoring target. The monitoring of the cathode voltage will be described later. Note that the cathode voltage may be the control target, and the anode voltage may be the monitoring target. In the present description, the voltage on the control target side is referred to as a bias voltage. That is, the anode voltage is referred to as a bias voltage in some cases.

FIG. 6 is a block diagram illustrating an example of the monitor pixel 401 according to the first embodiment of the present technology. As described above, the light receiving element 211 in the pixel chip 201 and the monitor pixel circuit 310 in the circuit chip 202 constitute one monitor pixel 401. The light receiving element 211 and the monitor pixel circuit 310 are connected via a chip connecting part 311. In the present description, an input node of the monitor pixel circuit 310 connected to the chip connecting part 311 is referred to as a connection node 312. The chip connecting part 311 is a portion that connects wiring inside the pixel chip 201 and wiring inside the circuit chip 202 by, for example, Cu—Cu bonding.

The monitor pixel circuit 310 includes a p-channel metal oxide semiconductor (pMOS) transistor 321, an n-channel metal oxide semiconductor (nMOS) transistor 322, a sample-and-hold circuit 340, and an analog-to-digital converter (ADC) 350. Furthermore, the monitor pixel circuit 310 may include an inverter 330 and a distance measuring unit 360.

The light receiving element 211 draws a current in response to incidence of photons. For example, the SPAD described above is used as the light receiving element 211.

The pMOS transistor 321 is inserted between the cathode of the light receiving element 211 and a power supply voltage VDDH. A certain constant voltage RCH to be operated as a current source is input to the gate of the pMOS transistor 321, and the cathode voltage of the light receiving element 211 is initialized to the power supply voltage VDDH via the connection node 312. Meanwhile, the nMOS transistor 322 is inserted between the cathode of the light receiving element 211 and a ground voltage VSS. When a high-level control signal SM from the timing generation unit 220 is input to the gate, the nMOS transistor 322 forcibly sets the cathode of the light receiving element 211 to the ground voltage VSS via the connection node 312. When the cathode of the light receiving element 211 is set to the ground voltage VSS, the light receiving element 211 stops the light receiving operation.

A voltage (cathode voltage VSM) of the connection node 312 connected to the cathode of the light receiving element 211 corresponds to the monitoring target voltage. The analog-to-digital converter (ADC) 350 is connected to the connection node 312 via the sample-and-hold circuit 340. When the light receiving element 211 receives photons and the cathode voltage VSM decreases, the sample-and-hold circuit 340 holds the cathode voltage. The analog-to-digital converter 350 determines how much difference there is between the held voltage and a desired quench voltage, and meanwhile, the anode of the light receiving element 211 is connected to the bias control unit 500 and an anode voltage VRLD thereof is controlled by the bias control unit 500.

The analog-to-digital converter 350 is inserted between the sample-and-hold circuit 340 and the bias control unit 500. This analog-to-digital converter 350 generates a digital signal indicating how much difference there is between the held voltage of the sample-and-hold circuit 340 and the desired quench voltage.

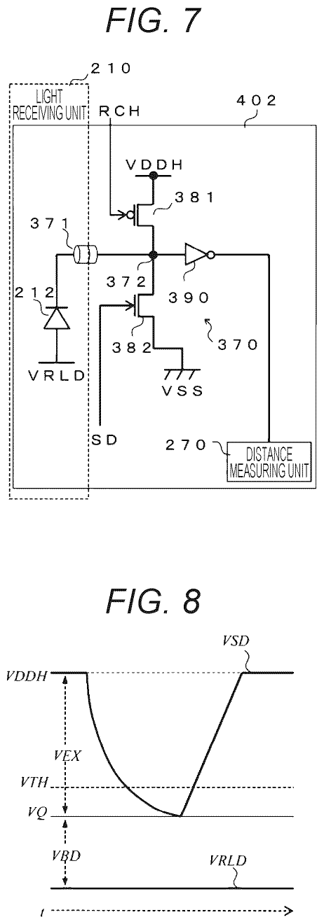

FIG. 7 is a block diagram illustrating an example of the distance measuring pixel according to the first embodiment of the present technology. As described above, the light receiving element 212 in the pixel chip 201 and the distance measuring pixel circuit 370 in the circuit chip 202 constitute one distance measuring pixel 402. The light receiving element 212 and the distance measuring pixel circuit 370 are connected via a chip connecting part 371. The chip connecting part 371 and the distance measuring pixel circuit 370 are connected via a connection node 372.

The distance measuring pixel circuit 370 includes a p-channel metal oxide semiconductor (pMOS) transistor 381 and an n-channel metal oxide semiconductor (nMOS) transistor 382, an inverter 390, and the distance measuring unit 270.

The pMOS transistor 381 is inserted between the light receiving element 212 and the power supply voltage VDDH. When a certain constant voltage RCH to be operated as a current source is input to the gate of the pMOS transistor 381, the cathode voltage of the light receiving element 212 is initialized to the power supply voltage VDDH via the connection node 372. Meanwhile, the nMOS transistor 382 is inserted between the cathode of the light receiving element 212 and the ground voltage VSS. When a high-level control signal SD is input to the gate of the nMOS transistor 382, the nMOS transistor 382 forcibly sets the cathode of the light receiving element 212 to the ground voltage VSS via the connection node 372. When the cathode of the light receiving element 212 is set to the ground voltage VSS, the light receiving element 212 stops the light receiving operation.

The cathode voltage of the light receiving element 212 is input to the inverter 390 via the connection node 372. The output voltage of the inverter 390 changes depending on whether or not the cathode voltage of the light receiving element 212 falls below the threshold voltage of the inverter 390. The output voltage of the inverter 390 is input to the distance measuring unit 270. The distance measuring unit 270 includes a time-to-digital converter, a histogram generation unit, a gravity center calculation unit, a distance calculation unit, and the like.

The cathode of the light receiving element 212 is connected to the connection node 372. Meanwhile, the anode of the light receiving element 212 is connected to the bias control unit 500, and the anode voltage VRLD thereof is controlled by the bias control unit 500. In this manner, the bias control unit 500 controls the anode voltages VRLD of the light receiving elements 211 and 212 to the same voltage.

FIG. 8 is a diagram illustrating a manner that a cathode voltage VSD of the light receiving element 212 in the distance measuring pixel 402 changes. In the initial state, the cathode voltage VSD is set to the power supply voltage VDDH which is an initial voltage. When photons are incident on the light receiving element 212, the cathode voltage VSD rapidly falls. The minimum value of the cathode voltage VSD is a quench voltage VQ. When the cathode voltage VSD falls below a threshold voltage VTH of the inverter 390, the output logic of the inverter 390 is inverted. Thereafter, the cathode voltage VSD is initialized to the original power supply voltage VDDH by recharge processing. The potential difference between the power supply voltage VDDH and the quench voltage VQ is referred to as an excess bias VEX. Furthermore, the potential difference between the quench voltage VQ and the anode voltage VRLD is referred to as a breakdown voltage VBD. In a case where the power supply voltage VDDH and the anode voltage VRLD are constant, the excess bias VEX and the breakdown voltage VBD vary depending on the temperature or the like.

As described above, when the cathode voltage VSD of the light receiving element 212 falls below the threshold voltage VTH of the inverter 390, a pulse signal is output from the inverter 390. The distance measuring unit 270 generates a digital signal representing the light reception timing on the basis of the pulse signal output from the inverter 390.

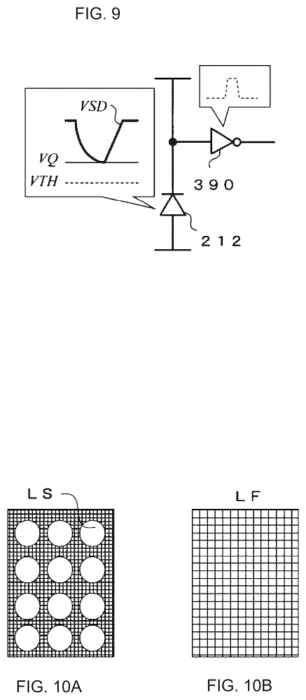

The excess bias VEX illustrated in FIG. 8 changes according to the temperature, and in some cases, the cathode voltage VSD does not fall below the threshold voltage VTH of the inverter 390 even though the light receiving element 212 has received photons. In particular, as the temperature rises, the excess bias VEX tends to be smaller. FIG. 9 is a diagram illustrating an example in which the excess bias VEX is small. As described above, when the excess bias VEX is small, there is a case where the cathode voltage VSD of the light receiving element 212 does not fall below the threshold voltage VTH of the inverter 390. Alternatively, there is a case where it takes time for the cathode voltage VSD to fall below the threshold voltage VTH. In the former case, the pulse signal is not output from the inverter 390 even though the photons are incident, and the distance measurement cannot be performed. In the latter case, a shift occurs in photon detection timing, and an error occurs in a distance measurement position.

Therefore, the bias control unit 500 continuously monitors the cathode voltage VSM of the light receiving element 211 in the monitor pixel 401 within a distance measuring period, and performs bias control to control the anode voltages VRLD of the monitor pixel 401 and the light receiving elements 211 and 212 in the distance measuring pixel 402 according to a degree of decrease in the cathode voltage VSM. More specifically, as the degree of decrease in the cathode voltage VSM of the light receiving element 211 becomes smaller, bias control to further decrease the anode voltage VRLD is performed. By performing such bias control, even if the temperature changes, the excess bias VEX of the light receiving element 212 can be controlled to be substantially constant, and PDE and the calculation accuracy of the distance measurement position is improved.

The distance measuring processing is intermittently performed with a distance measuring stop period in between. When the surrounding brightness greatly changes during the distance measuring stop period, there are cases where the cathode voltage VSM of the light receiving element 211 becomes a value different from that in the immediately preceding distance measuring period at the time of starting the distance measuring processing thereafter, and the distance measuring accuracy temporarily decreases. As described above, the change in the surrounding brightness occurs, for example, in a case where a vehicle traveling inside the tunnel comes out of the tunnel, or in a case where switching is performed between the long-distance distance measuring mode (second mode) and the middle/short-distance distance measuring mode (first mode). Hereinafter, the reason why the surrounding brightness changes by switching between the long-distance distance measuring mode and the middle/short-distance distance measuring mode will be described.

FIG. 10 is a diagram illustrating spotlight LS used in the long-distance distance measuring mode and floodlight LF used in the middle/short-distance distance measuring mode. In a case where the long-distance distance measuring mode is selected, because laser power needs to be increased in order to perform irradiation to a distant place, it is necessary to irradiate an object in a desired range with the light pulse signal by a limited number of light emitting elements, and thus, the spotlight LS is used. On the other hand, in a case where the middle/short-distance measuring mode selected, the laser power can be reduced as compared with the long-distance distance measuring mode. However, because the larger number of light emitting elements are required to emit light in order to irradiate a wide range of objects with the light pulse signal, the floodlight LF is used. As illustrated in FIG. 10A, the spotlight LS is light emitted only by a part of the light emitting elements by evenly thinning out the plurality of light emitting elements in the light emitting unit 110. As illustrated in FIG. 10B, the floodlight LF is light that uniformly irradiates the inside of the light receiving unit 210, and the number of light emitting elements that simultaneously emit light is larger than that of the spotlight LS.

The spotlight LS and the floodlight LF greatly differ in the amount of the reflected light pulse signal incident on the SPADs constituting the light receiving elements 211 and 212. Therefore, for example, in a case where the spotlight LS is switched to the floodlight LF, the number of SPADs reactive to light (hereinafter, the number of lighted pixels) greatly increases and causes the temperature of the chip of the SPAD to increase and a degree of decrease in the cathode voltage VSD of the light receiving element 212 of the SPAD to decrease. In addition, also at the time of coming out from a dark tunnel to the bright outdoors or the like, there are cases where the amount of light incident on the SPAD greatly increases, the temperature of the chip of the SPAD increases, and the degree of decrease in the cathode voltage VSD of the light receiving element 212 decreases.

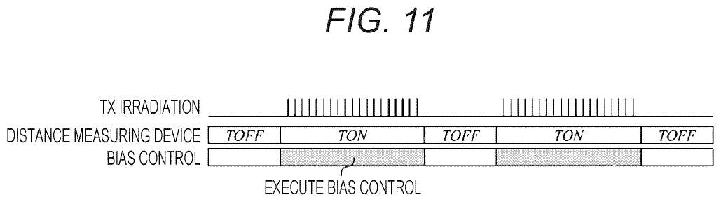

FIG. 11 is an operation timing diagram regarding the distance measuring processing and the bias control of the distance measuring device according to a comparative example. As illustrated in FIG. 11, a distance measuring period TON and a distance measuring stop period TOFF are alternately repeated. In the distance measuring period TON, the light emitting unit 110 repeatedly emits the light pulse signal, and in the distance measuring stop period TOFF, the light emitting unit 110 stops emitting the light pulse signal. Furthermore, the bias control is performed only in the distance measuring period TON.

In the case of FIG. 11, because the bias control is not performed within the distance measuring stop period TOFF, if the brightness of the surroundings greatly changes within the distance measuring stop period TOFF, there is a possibility that accurate distance measuring processing cannot be performed at the time of starting the subsequent distance measuring processing. In each embodiment described below, this problem can be solved.

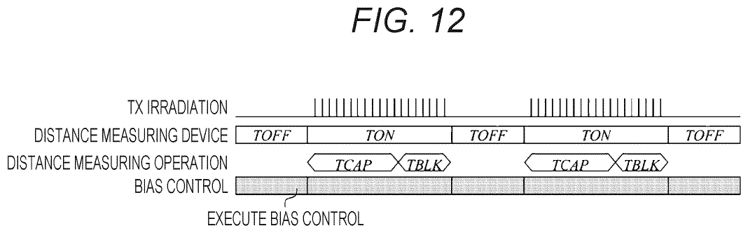

The distance measuring device according to the present embodiment operates the light receiving element 211 before starting the distance measuring processing, and performs the bias control of the light receiving elements 211 and 212. FIG. 12 is an operation timing diagram of the distance measuring device 200 and the light emitting unit 110 according to the first embodiment. In the first embodiment, the bias control of the light receiving elements 211 and 212 is performed in the distance measuring stop period TOFF before the distance measuring period TON. During the distance measuring stop period TOFF, because the light emitting unit 110 stops emitting the light pulse signal, the light receiving element 211 receives ambient light (also referred to as noise light). The bias control unit 500 controls the anode voltages VRLD of the light receiving elements 211 and 212 on the basis of a light reception result obtained by the light receiving element 211 during the distance measuring stop period TOFF.

Furthermore, in the distance measuring period TON, there are provided a capture period TCAP in which the light receiving elements 211 and 212 receive the reflected light pulse signal and perform the distance measuring processing, and as necessary, a blank period TBLK. The blank period TBLK is a period from the end of the capture period TCAP to the start of the next capture period TCAP. The blank period TBLK can be omitted, in which case multiple capture periods will be provided without interruption.

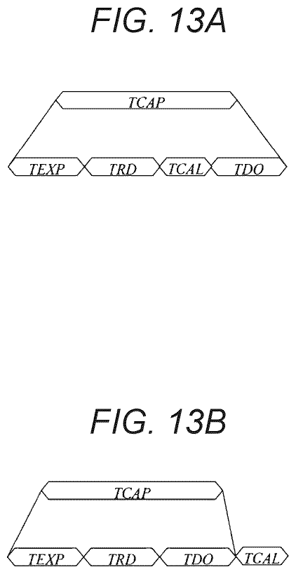

As illustrated in detail in FIG. 13A, the capture period TCAP includes, for example, an exposure period TEXP, a read period TRD, a calculation period TCAL, and a data output period TDO. The exposure period TEXP is a period in which the light receiving elements 211 and 212 receive the reflected light pulse signal. The read period TRD is a period in which the pulse signal output from the inverter 390 connected to the light receiving element 212 is converted into a digital signal and the histogram generation unit generates a histogram. The calculation period TCAL is a period in which the center of gravity is calculated on the basis of the histogram to identify the light reception timing, and the distance to the object is measured. The data output period TDO is a period in which a calculation processing result of the calculation period is output.

The calculation processing for distance measurement may be performed outside the distance measuring device 200 according to the present embodiment. In this case, as illustrated in detail in FIG. 13B, the capture period TCAP includes, for example, the exposure period TEXP, the read period TRD, and the data output period TDO, and the calculation period TCAL can be omitted.

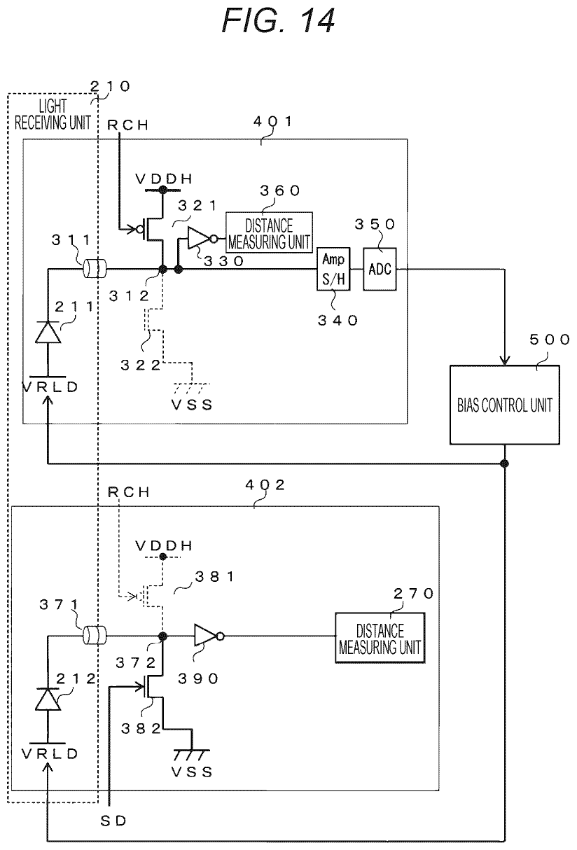

FIG. 14 is a diagram illustrating a circuit operation of the distance measuring device 200 during the distance measuring stop period TOFF in the first embodiment. As described above, the distance measuring device 200 includes the monitor pixel 401, the distance measuring pixel 402, and the bias control unit 500.

In the distance measuring stop period TOFF, the high-level control signal SD is input to the distance measuring pixel 402. With this configuration, the nMOS transistor 382 is turned on, the cathode of the light receiving element 212 in the distance measuring pixel 402 is forcibly set to the ground voltage VSS, and the light receiving element 212 in the distance measuring pixel 402 stops the light receiving operation.

Meanwhile, in the distance measuring stop period TOFF, a low-level control signal SM is input to the monitor pixel 401. With this configuration, the nMOS transistor 322 is turned off, and a certain constant voltage RCH for operating as a current source is input to the cathode voltage VSM of the light receiving element 211 in the monitor pixel 401, and the cathode voltage VSM is initialized by the recharge processing, so that the light receiving operation can be repeatedly performed.

Even in the distance measuring stop period TOFF, the bias control unit 500 performs the bias control on the basis of the light reception result of the light receiving element 211 in the monitor pixel 401, and performs the bias control to cause the cathode voltage VSD (quench voltage VQ) at the time when the light receiving element 212 reacts to photons to become a constant voltage level. With this configuration, the excess bias VEX illustrated in FIG. 8 does not fluctuate depending on the temperature, and thereafter, accurate distance measurement can be performed from the time point at which the distance measuring processing is started.

As described above, in the first embodiment, because the bias control of the light receiving elements 211 and 212 is performed not only in the distance measuring period TON but also in the distance measuring stop period TOFF, even if the surrounding brightness greatly changes during the distance measuring stop period between the distance measuring periods, the distance measuring processing can be accurately performed from the subsequent start time point of the distance measuring processing.

### Second Embodiment

In the first embodiment described above, during the distance measuring stop period TOFF, the bias control is performed by performing the light receiving operation only by the light receiving element 211 in the monitor pixel 401. Meanwhile, during the distance measuring period TON, not only the light receiving element 211 in the monitor pixel 401 but also the light receiving element 212 in the distance measuring pixel 402 performs the light receiving operation. When the distance measuring pixel 402 performs the light receiving operation, the number of the lighted light receiving elements 212 increases. Therefore, the amount of temperature rise changes as compared with the case where the light receiving operation is performed only by the light receiving element 211 in the monitor pixel 401. This causes the quench voltage VQ and the excess bias VEX described above to change, and thus, there is a possibility that the distance measuring accuracy decreases.

Therefore, in a second embodiment described below, in the distance measuring stop period TOFF, not only the light receiving element 211 in the monitor pixel 401 but also the light receiving element 212 in the distance measuring pixel 402 is caused to perform the light receiving operation to eliminate the amount of temperature error during the distance measuring period TON and to improve the distance measuring accuracy. That is, the light receiving element 212 in the distance measuring pixel 402 performs the light receiving operation within a period in which the light receiving element 211 in the monitor pixel 401 performs control of the bias voltage.

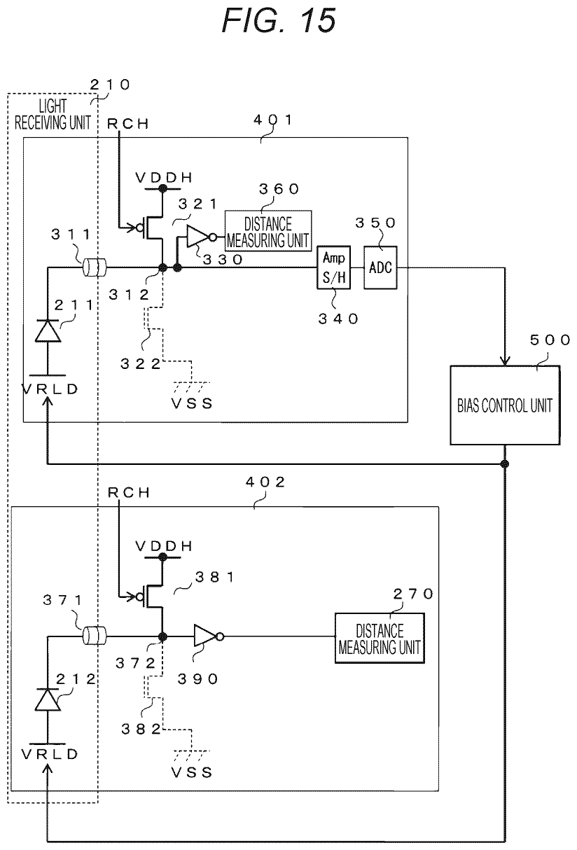

FIG. 15 is a diagram illustrating a circuit operation of the distance measuring device 200 during the distance measuring stop period TOFF according to the second embodiment. A low-level control signal SD is input to the distance measuring pixel 402 according to the second embodiment. With this configuration, the nMOS transistor 382 is turned off, and when a certain constant voltage RCH for operating as a current source is input, the cathode voltage VSD of the light receiving element 212 in the distance measuring pixel 402 is initialized by the recharge processing, and the light receiving operation can be repeatedly performed.

As described above, in the second embodiment, because the light receiving operation is performed not only by the light receiving element 211 in the monitor pixel 401 but also by the light receiving element 212 in the distance measuring pixel 402 in the distance measuring stop period TOFF, the amount of temperature error during the distance measuring period TON can be eliminated, and a decrease in the distance measuring accuracy immediately after the start of the distance measuring processing can be suppressed.

### Third Embodiment

In the first embodiment described above, only the light receiving element 211 in the monitor pixel 401 performs the light receiving operation in the distance measuring stop period TOFF. Meanwhile, in the second embodiment, the light receiving elements in all the pixels in a pixel chip 201 perform the light receiving operation during the distance measuring stop period TOFF, which causes the power consumption to increase. Therefore, in a third embodiment described below, only a part of the distance measuring pixels 402 perform the light receiving operation during the distance measuring stop period TOFF. Hereinafter, an example in which the distance measuring pixel 402 includes a distance measuring pixel 403 that performs the light receiving operation during the distance measuring stop period TOFF and a distance measuring pixel 404 that does not perform the light receiving operation during the distance measuring stop period TOFF will be described.

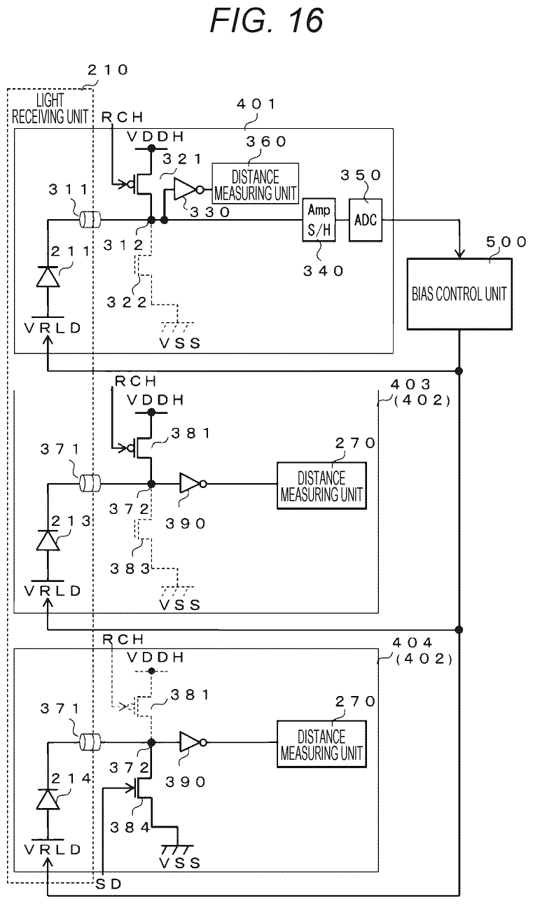

FIG. 16 is a diagram illustrating a circuit operation of the distance measuring device 200 during the distance measuring stop period TOFF according to the third embodiment. In the third embodiment, the low-level control signal SD is input to the distance measuring pixels 403 being a part of the distance measuring pixels to cause the light receiving operation to be performed, and a high-level control signal SD is input to the distance measuring pixels 404 being the remaining of the distance measuring pixels to cause the distance measuring pixels 404 to be in a light receiving stop state. Note that, similarly to the distance measuring pixel 402, the distance measuring pixels 403 and 404 include the light receiving elements 213 and 214 and the nMOS transistors 383 and 384, respectively. As described above, the light receiving elements 212 in the distance measuring pixels 403 being a part of the distance measuring pixels perform the light receiving operation within a period in which the light receiving element 211 in the monitor pixel 401 performs control of the bias voltage.

The distance measuring pixels 403 being a part of the distance measuring pixels and performing the light receiving operation during the distance measuring stop period TOFF are desirably, for example, distance measuring pixels obtained by evenly thinning out the plurality of distance measuring pixels 402 in the light receiving unit 210. By performing the light receiving operation in the distance measuring pixels 403 being a part of the distance measuring pixels and obtained by evenly thinning out the distance measuring pixels, the bias control can be performed by reflecting the temperature in the entire region of the light receiving unit 210.

As described above, in the third embodiment, because the light receiving operation is performed in the distance measuring pixels 403 being a part of the distance measuring pixels in addition to the monitor pixel 401 within the distance measuring stop period TOFF, the distance measuring processing can be performed with high accuracy from the distance measurement start time point with lower power consumption than in the second embodiment.

### Fourth Embodiment

In the first to third embodiments described above, the bias control is continuously performed during the distance measuring stop period TOFF. Therefore, the bias voltage of the anode can be controlled as a result of the stable temperature rise, but meanwhile, the power consumption increases as the distance measuring stop period TOFF becomes longer. Therefore, in a fourth embodiment described below, the bias control is performed in a partial period (hereinafter, a control period TJST) immediately before the distance measuring processing is started among the distance measuring stop period TOFF. In the fourth embodiment, similarly to the third embodiment, an example will be described in which the distance measuring pixel 402 includes the distance measuring pixel 403 that performs the light receiving operation during the distance measuring stop period TOFF and the distance measuring pixel 404 that does not perform the light receiving operation during the distance measuring stop period TOFF Note that the fourth embodiment can also be applied to a case where the light receiving operation is performed by all the distance measuring pixels 402 in the light receiving unit 210, or a case where the light receiving operation is performed only by the monitor pixel 401.

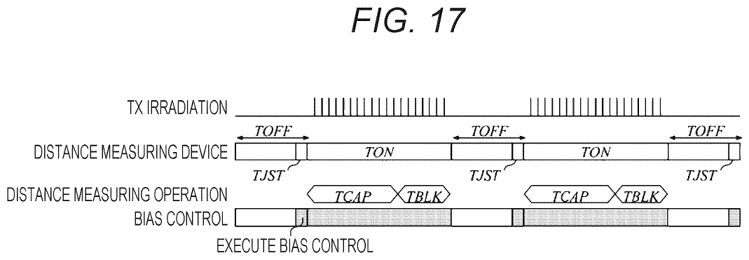

FIG. 17 is an operation timing diagram of the distance measuring device 200 and the light emitting unit 110 according to the fourth embodiment. FIG. 17 illustrates an example in which the bias control is performed by performing the light receiving operation in the monitor pixel 401 and the distance measuring pixels 403 being a part of the distance measuring pixels, in the control period TUST in the distance measuring stop period TOFF, the control period being several frames before the distance measuring period TON. The several frames mean one or more frames, and are not intended to be limited to a specific number of frames. Although the power consumption increases as the number of frames increases, the bias control with higher reliability can be performed. Therefore, it is desirable to set an appropriate number of frames in consideration of a balance between the power consumption and the reliability of the bias control.

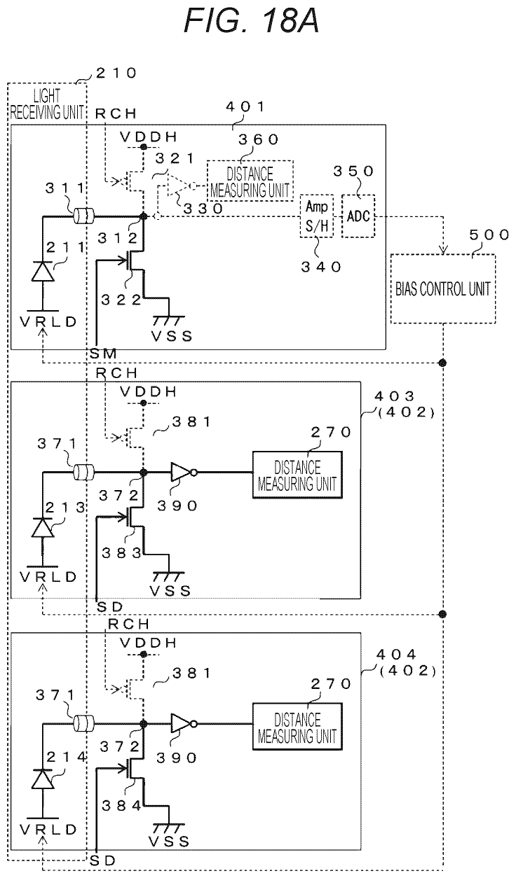

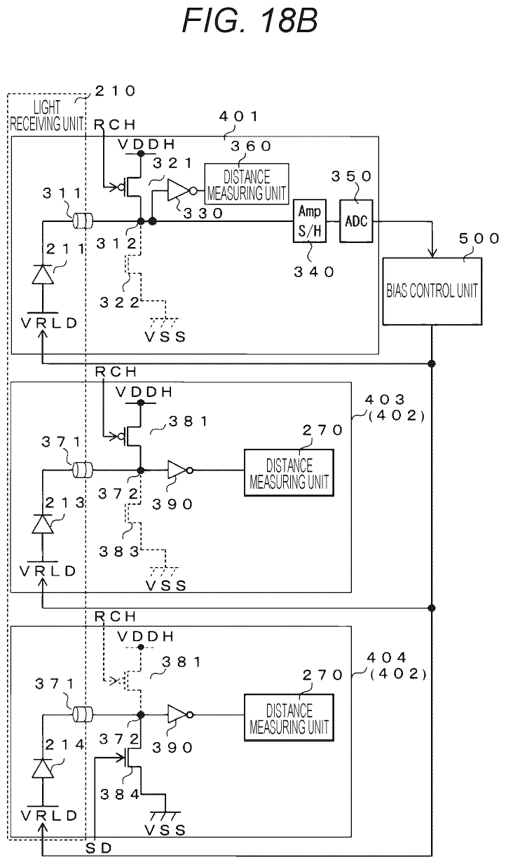

FIGS. 18A and 18B are diagrams illustrating circuit operations of the distance measuring device 200 according to the fourth embodiment. FIG. 18A is a diagram illustrating the circuit operation of the distance measuring device 200 in a period from the start point of the distance measuring stop period TOFF to the control period TJST. During this period, the monitor pixel 401 and all the distance measuring pixels 403 and 404 in the light receiving unit 210 stop the light receiving operation. Therefore, a control signal SM input to the gate of the nMOS transistor 322 connected to the cathode of the light receiving element 211 in the monitor pixel 401 becomes a high level, and the cathode of the light receiving element 211 is forcibly set to the ground voltage VSS. Similarly, within the above-described period, a control signal SD input to the gates of the nMOS transistors 383 and 384 connected to the cathodes of the light receiving elements 213 and 214 in the distance measuring pixels 403 and 404 becomes a high level, and the cathodes of the light receiving elements 213 and 214 are set to the ground voltage VSS. The light receiving element 211 in the monitor pixel 401 and the light receiving elements 213 and 214 in the distance measuring pixels 403 and 404 stop the light receiving operation.

FIG. 18B is a diagram illustrating the circuit operation of the distance measuring device 200 in the control period TJST. Similarly to FIG. 16, FIG. 18B illustrates an example in which the light receiving operation is performed by the monitor pixel 401 and the distance measuring pixels 403 being a part of the distance measuring pixels. In the light receiving element 211 of the monitor pixel 401 and the light receiving elements 213 of the distance measuring pixels 403 being a part of the distance measuring pixels, the cathode voltages VSM and VSD temporarily decrease each time when the light receiving elements react to photons, and the cathode voltages VSM and VSD are initialized by the subsequent recharge processing.

As described above, in the fourth embodiment, because the bias control is performed only in the control period TUST in the distance measuring stop period TOFF immediately before the start of the distance measuring processing, the power consumption can be suppressed.

### Fifth Embodiment

In the first to fourth embodiments described above, the bias control of each light receiving element is performed on the basis of the ambient light (also referred to as background light or noise light) received in the distance measuring stop period TOFF. In a case where the luminance of the ambient light is low, the luminance difference between the distance measuring stop period TOFF and the distance measuring period TON increases, and the temperature change of the light receiving unit 210 also increases. Therefore, there is a possibility that the bias control performed within the distance measuring stop period TOFF cannot be applied as it is in the distance measuring period TON. In particular, in the case of performing the distance measuring processing in the middle/short distance, because the reflected light pulse signal based on the floodlight LF that causes more light emitting elements in the light emitting unit 110 to emit light is received by the light receiving unit 210, the number of light receiving elements that react to photons rapidly increases and the temperature also increases, and thus, the bias control needs to be performed again. Therefore, in a fifth embodiment described below, the light emitting unit 110 intermittently emits the light pulse signal also within the distance measuring stop period TOFF, and performs the bias control under the same condition as the distance measuring period TON.

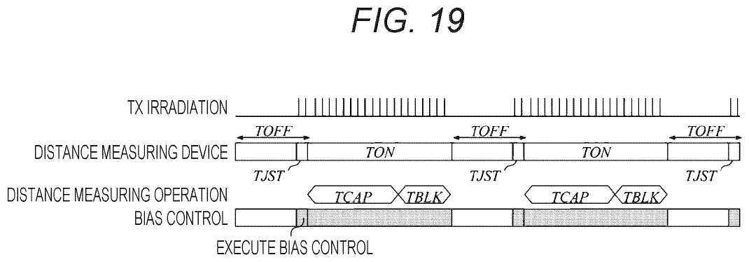

FIG. 19 is an operation timing diagram of the distance measuring device 200 and the light emitting unit 110 according to the fifth embodiment. In the fifth embodiment, the light emitting unit 110 intermittently emits the light pulse signal not in the distance measuring period TON but also in at least a part of the distance measuring stop period TOFF. An object is irradiated with the emitted light pulse signal, and a reflected light pulse signal from the object is received by the monitor pixel 401 and the distance measuring pixels 403 and 404. The monitor pixel 401 and the light receiving element 211 perform the bias control for controlling the anode voltage VRLD of each light receiving element on the basis of the light reception result of the reflected light pulse signal.

In a case of causing the floodlight LF to be emitted during the distance measuring period TON, there is a high possibility that the temperature change becomes significant. Therefore, the floodlight LF is desirably emitted also during the distance measuring stop period TOFF. Furthermore, in a case of causing the spotlight LS to be emitted during the distance measuring period TON, because the temperature change is not as remarkable as that in the case of the floodlight LF, the spotlight LS may not be emitted during the distance measuring stop period TOFF in consideration of power consumption. Alternatively, in a case of causing the spotlight to be emitted during the distance measuring period TON, the spotlight LS may also be emitted during the distance measuring stop period TOFF.

Furthermore, in the fifth embodiment, within the distance measuring stop period TOFF, the bias control may be performed by using all the distance measuring pixels 403 and 404 in addition to the monitor pixel 401 in the light receiving unit 210, the bias control may be performed by using the distance measuring pixels 403 being a part of the distance measuring pixels, or the bias control may be performed only by the monitor pixel 401. Moreover, the bias control may be performed only in the control period TJST.

As described above, in the fifth embodiment, because the light emitting unit 110 emits the light pulse signal to perform the bias control in at least the control period TJST being a part within the distance measuring stop period TOFF similarly to the distance measuring period TON, the difference in the amount of incident light to the pixel chip 201 can be suppressed between the distance measuring stop period TOFF and the distance measuring period TON, and the reliability of the bias control in the distance measuring stop period TOFF can be improved.

### Sixth Embodiment

In the first to fifth embodiments described above, the bias control is performed according to the degree of decrease in the cathode voltage VSM of the light receiving element 211 in the monitor pixel 401. In contrast, in a sixth embodiment described below, the number of times (hereinafter, a count value) is counted, the number of times being the one that the cathode voltages VSM and VSD of the light receiving elements 211 and 212 in the monitor pixel 401 and the distance measuring pixel 402 fall below the threshold voltages VTH of the inverters 330 and 390. This embodiment is different from the first to fifth embodiments in that the bias control is performed on the basis of the count value.

As in the first to fifth embodiments, in a case where the bias control is performed according to the degree of decrease in the cathode voltage VSM of the light receiving element 211, the bias voltage (for example, the anode voltage VRLD of the light receiving element 212) can be finely adjusted according to the temperature change. In contrast, in the sixth embodiment described below, because the bias control is performed by the number of times that the cathode voltages VSM and VSD of the light receiving elements 211 and 212 fall below the threshold voltages VTH of the inverters 330 and 390, the bias voltages of all the light receiving elements 211 and 212 in the light receiving unit 210 can be controlled only by operating a part of the pixels although the bias voltage cannot be finely adjusted with respect to the temperature change.

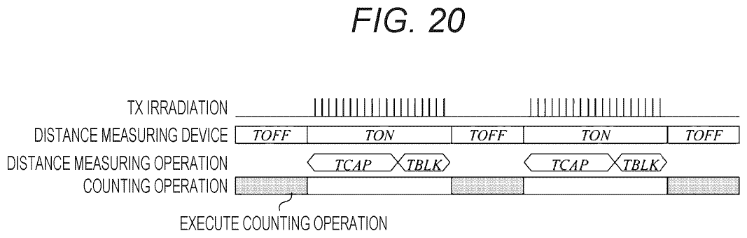

FIG. 20 is an operation timing diagram of the distance measuring device 200 and the light emitting unit 110 according to the sixth embodiment. In the sixth embodiment, the distance measuring device 200 performs a counting operation in the distance measuring stop period TOFF.

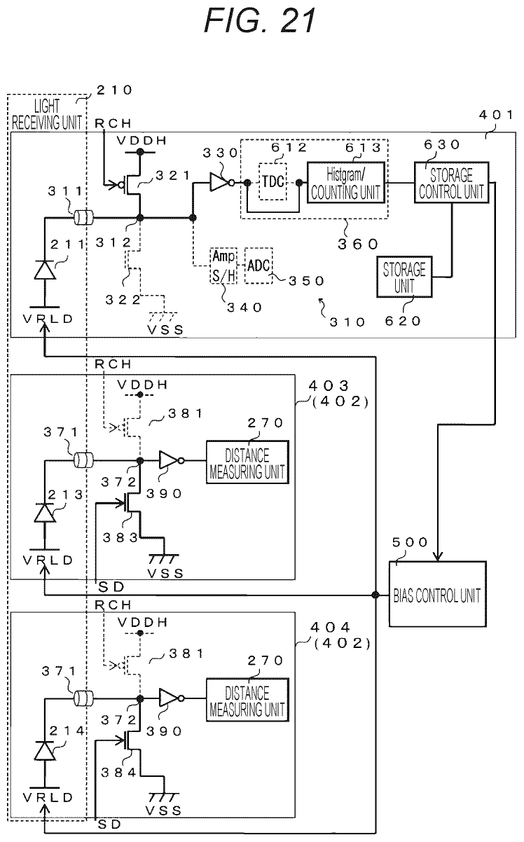

FIG. 21 is a diagram illustrating a circuit operation of the distance measuring device 200 according to the sixth embodiment. FIG. 21 is a diagram illustrating a case where the count value is monitored only by the monitor pixel 401 among the monitor pixel 401 and the distance measuring pixel 402 within the distance measuring stop period TOFF. In this case, the cathode voltage VSM of the light receiving element 211 of the monitor pixel 401 is set to the initialization voltage by the pMOS transistor 321, and the light receiving operation can be performed. On the other hand, the cathode of the light receiving element 212 of the distance measuring pixel 402 is set to the ground voltage VSS by the nMOS transistors 383 and 384, and the light receiving operation is forcibly stopped.

In the sixth embodiment, the monitor pixel circuit 310 counts the above-described count value by using a histogram generation unit/counting unit 613 in the distance measuring unit 360, a storage unit 620, and a storage control unit 630. A time-to-digital converter 612 disposed in the distance measuring unit 360 is used in the distance measuring processing but is not used in the counting processing and is bypassed.

When the photons are incident on the light receiving element 211 and the cathode voltage VSM falls below the threshold voltage VTH of the inverter 330, an inverted pulse signal is output from the inverter 330, and this inverted pulse signal becomes a digital signal. This digital signal is a binary signal indicating whether or not the cathode voltage VSM of the light receiving element 211 has fallen below the threshold voltage VTH of the inverter 330.

The histogram generation unit/counting unit 613 outputs the reaction frequency of photons as the count value on the basis of the digital signal described above within the distance measuring stop period TOFF.

The storage unit 620 stores a correspondence relationship between the average value of the count values counted by the individual light receiving elements 211, the quench voltage VQ of the light receiving elements 211, and the temperature. The information stored in the storage unit 620 is, for example, information measured and stored before shipping of the distance measuring device according to the present disclosure.

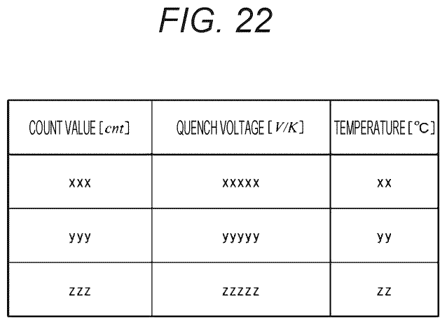

FIG. 22 is a diagram illustrating a data configuration of the storage unit 620. As illustrated in the drawing, the storage unit 620 stores a correspondence relationship between the average value of the count values, the quench voltage VQ of the light receiving element 211 or 212 in the monitor pixel 401, and the temperature. The quench voltage VQ of the light receiving elements 211 and 212 indicates the anode voltage VRLD that is bias controlled. Note that the temperature information in the storage unit 620 is not essential information from the viewpoint of estimating the quench voltage VQ from the count value.

The storage control unit 630 refers to the storage unit 620 on the basis of the count value output from the histogram generation unit/counting unit 613, and acquires the corresponding quench voltage VQ.

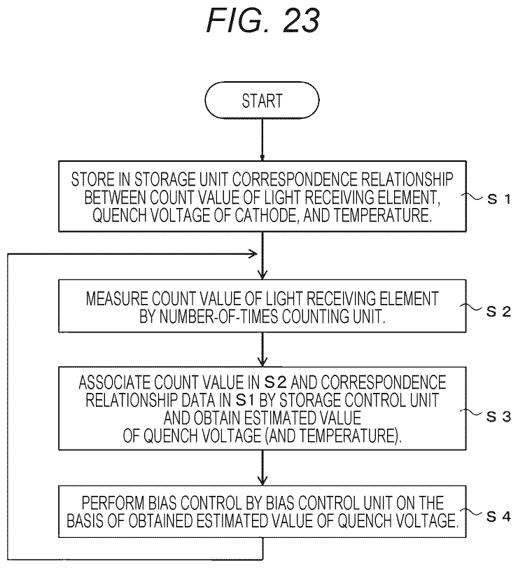

FIG. 23 is a flowchart illustrating a processing operation of the distance measuring device 200 in the sixth embodiment. This flowchart is performed within the distance measuring stop period TOFF.

First, the information in FIG. 22 is stored in the storage unit 620 (step S1). As described above, the processing of step S1 is performed, for example, before shipping of the distance measuring device. Alternatively, the information in FIG. 22 may be stored in the storage unit 620 at an optional timing according to an instruction by a user.

Next, the monitor pixel 401 is used to count the number of times that the cathode voltage VSM of the light receiving element 211 falls below the threshold voltage VTH of the inverter 330 within the distance measuring stop period TOFF (step S2). More specifically, in step S2, the histogram generation unit/counting unit 613 calculates the average value of the count values of the plurality of light receiving elements 211 that counts the number of times.

Next, the corresponding quench voltage VQ is acquired with reference to the storage unit 620 on the basis of the count value counted in step S2 (step S3). The processing in step S3 is performed by the storage control unit 630.

Next, the bias control is performed to control the anode voltage VRLD of each of the light receiving elements 211 and 212 so that the cathode voltages VSM and VSD of the corresponding ones of the light receiving elements 211 and 212 in the light receiving unit 210 become the quench voltage VQ acquired in step S3 at the time of photon reaction (step S4). The control in step S4 is performed by the bias control unit 500.

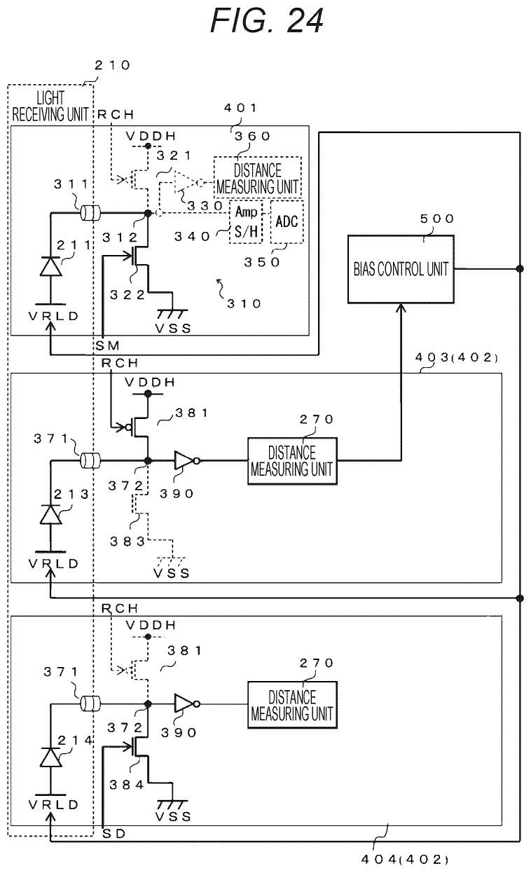

The processing in steps S2 to S4 in FIG. 23 is performed every distance measuring stop period TOFF. The case where the count value in step S2 is counted only by the monitor pixel 401 as illustrated in FIG. 21 has been described above. Note that, as a modification, as illustrated in FIG. 24, counting may be performed only in the distance measuring pixels 403 being a part of the distance measuring pixels, or counting may be performed in all of the distance measuring pixels 402. In a case where the distance measuring pixel 403 or 404 performs counting, the number of times that the cathode voltage VSD of the corresponding ones of the light receiving elements 213 and 214 falls below the threshold voltage VTH of the inverter 390 is counted. Note that the storage unit 620 in FIG. 21 may be provided separately from the distance measuring device 200. Furthermore, in FIG. 24, a storage unit that stores the count value counted by the distance measuring unit 270 is omitted, but this storage unit may be provided separately from the distance measuring device 200.

FIG. 24 is a diagram illustrating a case where the count value is monitored only by the distance measuring pixels 403 being a part of the pixels, among the monitor pixels 401 and the distance measuring pixels 402. In a case where the count value is monitored only by the distance measuring pixels 403 being a part of the pixels, during the distance measuring stop period TOFF, the cathodes of the monitor pixel 401 and the light receiving elements 211 and 214 of the distance measuring pixel 404 not performing the count value monitoring are forcibly set to the ground voltage VSS by the nMOS transistors 322 and 384, and the light receiving operation is stopped.

The distance measuring pixel circuit 370 in FIG. 24 counts the reaction frequency of photons in the distance measuring unit 270.

Similarly to the case where the count value is monitored only by the monitor pixel 401, also in the distance measuring pixel 403, the quench voltage VQ of the light receiving element 213 can be estimated by using the count value and the storage unit, and the bias control can be performed on the basis of the estimated quench voltage VQ.

As described above, in the sixth embodiment, the bias control is not performed on the basis of the cathode voltage VSM of the light receiving element 211 in the monitor pixel 401, but the bias control is performed on the basis of the number of times that the cathode voltage VSM or VSD falls below the threshold voltage VTH of the inverters 330 and 390. Therefore, the anode voltage VRLD of the light receiving elements 211 and 212 can be controlled only by operating a part of the pixels without causing concern about the difference in temperature change. Furthermore, because the correspondence relationship between the count value, the quench voltage VQ, and the temperature is stored in the storage unit 620 in advance, the quench voltage VQ can be acquired from the measured count value with reference to the storage unit 620 to set the bias voltage, and the bias control can be quickly performed.

### Seventh Embodiment

In the sixth embodiment described above, the counting operation is continuously performed in the distance measuring stop period TOFF. On the other hand, in a seventh embodiment described below, similarly to the fourth embodiment, the period in which the counting operation is performed is limited to the control period TJST to suppress the power consumption.

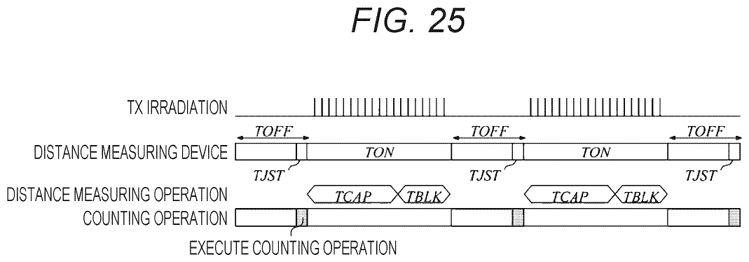

FIG. 25 is an operation timing diagram of the distance measuring device 200 and the light emitting unit 110 according to the seventh embodiment. In the seventh embodiment, the counting operation is performed in the control period TJST in the distance measuring stop period TOFF immediately before the distance measuring period TON.

As described above, in the seventh embodiment, because the counting operation is performed only in the control period TJST which is a part of the distance measuring stop period TOFF, the power consumption can be further suppressed.

### Eighth Embodiment

In the sixth to seventh embodiments described above, the bias control of each light receiving element is performed on the basis of the ambient light received in the distance measuring stop period TOFF. On the other hand, in an eighth embodiment described below, similarly to the fifth embodiment, by the light emitting unit 110 performing the light emitting operation also during the distance measuring stop period TOFF, the reliability of the bias control in the distance measuring stop period TOFF is improved.

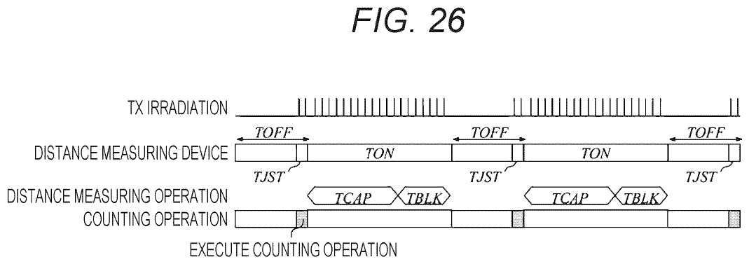

FIG. 26 is an operation timing diagram of the distance measuring device 200 and the light emitting unit 110 according to the eighth embodiment. In the eighth embodiment, similarly to the fifth embodiment, the light emitting unit 110 intermittently emits the light pulse signal also in the distance measuring stop period TOFF.

As described above, in the eighth embodiment, because the light emitting unit 110 emits the light pulse signal to perform the counting operation in at least the counting operation period being a part of the distance measuring stop period TOFF similarly to the distance measuring period TON, the difference in the amount of light incident on the pixel chip 201 can be suppressed between the distance measuring stop period TOFF and the distance measuring period TON, and the reliability of the bias control within the distance measuring stop period TOFF can be improved.

### Application Example

The technology according to the present disclosure can be applied to various products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, a robot, a construction machine, an agricultural machine (tractor).

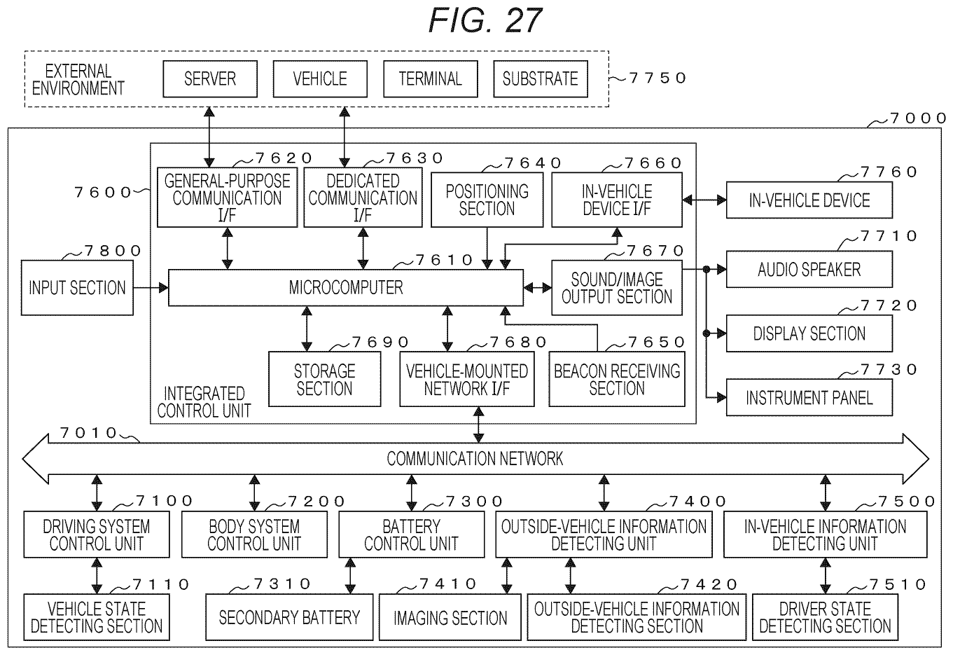

FIG. 27 is a block diagram illustrating a schematic configuration example of a vehicle control system 7000 as an example of a mobile body control system to which the technology of the present disclosure is applied. The vehicle control system 7000 includes a plurality of electronic control units connected to each other via a communication network 7010. In the example illustrated in FIG. 27, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 27 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

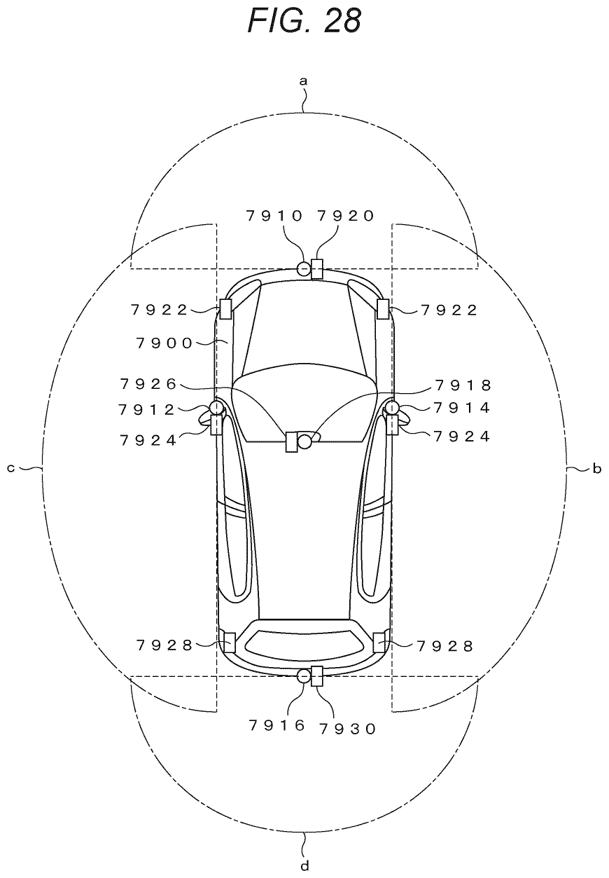

Here, FIG. 28 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 28 illustrates an example of an imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 27, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 27, an audio speaker 7710, a display section 7720, and an instrument panel 7730 are illustrated as output devices. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 27, at least two control units connected to each other via the communication network 7010 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementing each function of the distance measuring device 200 according to the present embodiment described with reference to FIG. 14 and the like can be implemented in any of the control units or the like. Furthermore, a computer-readable recording medium in which such a computer program is stored can be provided. The recording medium is, for example, a magnetic disk, an optical disk, a magneto-optical disk, a flash memory, or the like. Furthermore, the computer program described above may be distributed via, for example, a network without using a recording medium.

In the vehicle control system 7000 described above, the distance measuring device 200 according to the present embodiment described with reference to FIG. 14 and the like can be applied to the integrated control unit 7600 of the application example illustrated in FIG. 17. For example, the processing operation of the distance measuring unit 270 of the distance measuring device 200 can be performed by the microcomputer 7610, the storage section 7690, and the vehicle-mounted network I/F 7680 of the integrated control unit 7600.

Furthermore, at least a part of the components of the distance measuring device 200 described with reference to FIG. 14 and the like may be implemented in a module (for example, an integrated circuit module constituted of one die) for the integrated control unit 7600 illustrated in FIG. 17. Alternatively, the distance measuring device 200 described with reference to FIG. 14 and the like may be implemented by a plurality of control units of the vehicle control system 7000 illustrated in FIG. 17.

Note that the present technology may have the following configurations.
(1) A distance measuring device including: a light receiving unit that receives a reflected light pulse signal reflected by an object; a distance measuring unit that performs distance measuring processing on the basis of an output signal of the light receiving unit; and a bias control unit that controls a bias voltage of the light receiving unit before the distance measuring unit starts the distance measuring processing.
(2) The distance measuring device according to (1), in which the bias control unit controls a bias voltage of the light receiving unit in a first period before the distance measuring unit starts the distance measuring processing and a second period during which the distance measuring processing is performed.
(3) The distance measuring device according to (2), in which the first period includes a partial period immediately before the distance measuring processing is started among a period in which the distance measuring processing is not performed.
(4) The distance measuring device according to any one of (1) to (3), in which
the light receiving unit includes: a first light receiving element used for the distance measuring processing; and
a second light receiving element used to control the bias voltage.
(5) The distance measuring device according to any one of (1) to (3), in which the light receiving unit includes:
a first light receiving element used for the distance measuring processing; and a second light receiving element used to control the bias voltage, and the first light receiving element performs a light receiving operation to contribute to control of the bias voltage.
(6) The distance measuring device according to any one of (1) to (3), in which the light receiving unit includes:
a plurality of first light receiving elements used in the distance measuring processing; and a second light receiving element used to control the bias voltage, and a part of the first light receiving elements among the plurality of first light receiving elements performs the distance measuring processing and also performs a light receiving operation to contribute to control of the bias voltage.
(7) The distance measuring device according to (6), including a pixel array unit including the plurality of first light receiving elements, in which the part of the first light receiving elements are two or more first light receiving elements obtained by thinning out the plurality of first light receiving elements in the pixel array unit, the part of the first light receiving elements performing the distance measuring processing and also performing the light receiving operation to contribute to control of the bias voltage.
(8) The distance measuring device according to any one of (1) to (7), in which the bias control unit controls the bias voltage on the basis of a voltage level of an output signal of the light receiving unit before the distance measuring unit starts the distance measuring processing.
(9) The distance measuring device according to any one of (1) to (7), in which the bias control unit controls the bias voltage on the basis of a voltage level of an output signal of the light receiving unit that has received the reflected light pulse signal before the distance measuring unit starts the distance measuring processing.
(10) The distance measuring device according to any one of (4) to (7), in which the bias voltage is controlled to cause a cathode voltage or an anode voltage of the first light receiving element to become a predetermined voltage level when the first light receiving element receives the reflected light pulse signal.
(11) The distance measuring device according to any one of (1) to (3), in which the bias control unit controls the bias voltage on the basis of the number of crossing times between an output signal of the light receiving unit and a predetermined threshold.
(12) The distance measuring device according to any one of (1) to (3), in which
the light receiving unit includes a plurality of light receiving elements, and
the bias control unit controls the bias voltage on the basis of the number of crossing times between output signals of at least a part light receiving elements among the plurality of light receiving elements and a predetermined threshold.
(13) The distance measuring device according to (11) or (12), including: a number-of-times counting unit that counts the number of crossing times; a storage unit that stores a correspondence relationship between the number of times that an output signal of the light receiving unit crosses a predetermined threshold and an output signal level of the light receiving unit; and a storage control unit that reads, from the storage unit, the output signal level corresponding to the number of times counted by the number-of-times counting unit, in which the bias control unit controls the bias voltage on the basis of the output signal level read by the storage control unit.
(14) The distance measuring device according to (13), in which the storage unit stores a correspondence relationship between the number of times that an output signal of the light receiving unit crosses a predetermined threshold, the output signal level of the light receiving unit, and the temperature.
(15) The distance measuring device according to (13) or (14), in which the number-of-times counting unit counts the number of times that an output signal of the light receiving unit crosses the predetermined threshold, the light receiving unit having received the reflected light pulse signal before the distance measuring unit starts the distance measuring processing.
(16) A distance measuring system, further including:
the distance measuring device according to any one of (1) to (15); and a light emitting unit that emits a light pulse signal, in which the light receiving unit receives the reflected light pulse signal obtained by reflecting the light pulse signal by the object.
(17) The distance measuring system according to (16), in which the light emitting unit emits the light pulse signal during a period in which the distance measuring processing is performed and a period in which the bias control unit controls a bias voltage of the light receiving unit before starting the distance measuring processing.
(18) The distance measuring system according to (17), in which the distance measuring unit measures a distance to the object on the basis of a time difference between a light emission timing of the light pulse signal by the light emitting unit and a light reception timing of the reflected light pulse signal by the light receiving unit.
(19) The distance measuring system according to any one of (16) to (18), in which
the light emitting unit includes a plurality of light emitting elements each of which emits the light pulse signal,
the light emitting unit has a first mode of causing one or more first number of pieces of the light emitting elements to simultaneously emit light at a time when the distance measuring unit measures a distance to the object within a first distance range, and a second mode of causing a second number of pieces of the light emitting elements less than the first number of pieces to simultaneously emit light at a time when the distance measuring unit measures a distance to the object within a second distance range wider than the first distance range, and,
in the first mode, the light emitting unit causes the first number of pieces of light emitting elements to simultaneously emit light in a period in which the distance measuring unit performs the distance measuring processing and before the distance measuring unit starts the distance measuring processing, and in the second mode, the light emitting unit does not cause the second number of pieces of light emitting elements to simultaneously emit light before the distance measuring unit starts the distance measuring processing and causes the second number of pieces of light emitting elements to simultaneously emit light within a period in which the distance measuring unit performs the distance measuring processing.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

100 Distance measuring system
110 Light emitting unit
120 Synchronization control unit
200 Distance measuring device
201 Pixel chip
202 Circuit chip
210 Light receiving unit
211, 212, 213, 214 Light receiving element
220 Timing generation unit
260 Output interface
270, 360 Distance measuring unit
300 Circuit block
310 Monitor pixel circuit
311, 371 Chip connecting part
312, 372 Connection node
321, 381 pMOS transistor
322, 382, 383, 384 nMOS transistor
330, 390 Inverter
340 Sample-and-hold circuit
350 Analog-to-digital converter
370 Distance measuring pixel circuit
401 Monitor pixel
402, 403, 404 Distance measuring pixel
500 Bias control unit
612 Time-to-digital converter
613 Histogram generation unit/counting unit
620 Storage unit
630 Storage control unit

1. A distance measuring device comprising:
a light receiving unit that receives a reflected light pulse signal reflected by an object;
a distance measuring unit that performs distance measuring processing on a basis of an output signal of the light receiving unit; and
a bias control unit that controls a bias voltage of the light receiving unit before the distance measuring unit starts the distance measuring processing.

2. The distance measuring device according to claim 1, wherein the bias control unit controls a bias voltage of the light receiving unit in a first period before the distance measuring unit starts the distance measuring processing and a second period during which the distance measuring processing is performed.

3. The distance measuring device according to claim 2, wherein the first period includes a partial period immediately before the distance measuring processing is started among a period in which the distance measuring processing is not performed.

4. The distance measuring device according to claim 1, wherein
the light receiving unit includes:
a first light receiving element used for the distance measuring processing; and
a second light receiving element used to control the bias voltage.

5. The distance measuring device according to claim 1, wherein
the light receiving unit includes:
a first light receiving element used for the distance measuring processing; and
a second light receiving element used to control the bias voltage, and
the first light receiving element performs a light receiving operation within a period in which the second light receiving element controls the bias voltage.

6. The distance measuring device according to claim 1, wherein
the light receiving unit includes:
a plurality of first light receiving elements used in the distance measuring processing; and
a second light receiving element used to control the bias voltage, and
a part of the first light receiving elements among the plurality of first light receiving elements perform a light receiving operation within a period in which the second light receiving element controls the bias voltage.

7. The distance measuring device according to claim 6, comprising
a pixel array unit including the plurality of first light receiving elements, wherein
the part of the first light receiving elements are two or more first light receiving elements obtained by thinning out the plurality of first light receiving elements in the pixel array unit.

8. The distance measuring device according to claim 1, wherein the bias control unit controls the bias voltage on a basis of a voltage level of an output signal of the light receiving unit before the distance measuring unit starts the distance measuring processing.

9. The distance measuring device according to claim 1, wherein the bias control unit controls the bias voltage on a basis of a voltage level of an output signal of the light receiving unit that has received the reflected light pulse signal before the distance measuring unit starts the distance measuring processing.

10. The distance measuring device according to claim 4, wherein the bias voltage is controlled to cause a cathode voltage or an anode voltage of the first light receiving element to become a predetermined voltage level when the first light receiving element receives the reflected light pulse signal.

11. The distance measuring device according to claim 1, wherein the bias control unit controls the bias voltage on a basis of a number of crossing times between an output signal of the light receiving unit and a predetermined threshold.

12. The distance measuring device according to claim 1, wherein
the light receiving unit includes a plurality of light receiving elements, and
the bias control unit controls the bias voltage on a basis of a number of crossing times between output signals of at least a part of light receiving elements among the plurality of light receiving elements and a predetermined threshold.

13. The distance measuring device according to claim 11, comprising:
a number-of-times counting unit that counts the number of crossing times;
a storage unit that stores a correspondence relationship between a number of times that an output signal of the light receiving unit crosses a predetermined threshold and an output signal level of the light receiving unit; and
a storage control unit that reads, from the storage unit, the output signal level corresponding to a number of times counted by the number-of-times counting unit, wherein
the bias control unit controls the bias voltage on a basis of the output signal level read by the storage control unit.

14. The distance measuring device according to claim 13, wherein the storage unit stores a correspondence relationship between a number of times that an output signal of the light receiving unit crosses a predetermined threshold, the output signal level of the light receiving unit, and a temperature.

15. The distance measuring device according to claim 13, wherein the number-of-times counting unit counts a number of times that an output signal of the light receiving unit crosses the predetermined threshold, the light receiving unit having received the reflected light pulse signal before the distance measuring unit starts the distance measuring processing.

16. A distance measuring system, further comprising:
the distance measuring device according to claim 1; and
a light emitting unit that emits a light pulse signal, wherein
the light receiving unit receives the reflected light pulse signal obtained by reflecting the light pulse signal by the object.

17. The distance measuring system according to claim 16, wherein the light emitting unit emits the light pulse signal during a period in which the distance measuring processing is performed and a period in which the bias control unit controls a bias voltage of the light receiving unit before starting the distance measuring processing.

18. The distance measuring system according to claim 17, wherein the distance measuring unit measures a distance to the object on a basis of a time difference between a light emission timing of the light pulse signal by the light emitting unit and a light reception timing of the reflected light pulse signal by the light receiving unit.

19. The distance measuring system according to claim 16, wherein
the light emitting unit includes a plurality of light emitting elements each of which emits the light pulse signal,
the light emitting unit has a first mode of causing one or more first number of pieces of the light emitting elements to simultaneously emit light at a time when the distance measuring unit measures a distance to the object within a first distance range, and a second mode of causing a second number of pieces of the light emitting elements less than the first number of pieces to simultaneously emit light at a time when the distance measuring unit measures a distance to the object within a second distance range wider than the first distance range, and,
in the first mode, the light emitting unit causes the first number of pieces of light emitting elements to simultaneously emit light in a period in which the distance measuring unit performs the distance measuring processing and before the distance measuring unit starts the distance measuring processing, and in the second mode, the light emitting unit does not cause the second number of pieces of light emitting elements to simultaneously emit light before the distance measuring unit starts the distance measuring processing and causes the second number of pieces of light emitting elements to simultaneously emit light within a period in which the distance measuring unit performs the distance measuring processing.
